(19) United States
(12) Patent Application Publication
(10) Pub. No.: US 2022/0246557 A1
(43) Pub. Date: Aug. 4, 2022

(54) PACKAGE CHIP AND METHOD OF MANUFACTURING THE SAME, REWIRING PACKAGE CHIP AND METHOD OF MANUFACTURING THE SAME

(71) Applicant: SHENNAN CIRCUITS CO., LTD., SHENZHEN (CN)

(72) Inventors: LIXIANG HUANG, SHENZHEN (CN); HUA MIAO, SHENZHEN (CN)

(21) Appl. No.: 17/724,438

(22) Filed: Apr. 19, 2022

Related U.S. Application Data
(63) Continuation of application No. PCT/CN2021/103811, filed on Jun. 30, 2021.

(51) Int. Cl. H01L 23/00; H01L 21/56; H01L 23/31

(52) U.S. Cl. CPC H01L 24/03; H01L 21/56; H01L 23/291; H01L 24/05; H01L 23/3114; H01L 23/3135

(57) ABSTRACT

A method of manufacturing a package chip, a package chip, a method of manufacturing a rewiring package chip, and a rewiring package chip are provided. Since a dielectric layer covering a surface of a chip and conductive surfaces of pads does not need to be partially removed by etching, air tightness of the package chip may be improved to prevent the pads from being oxidized by the air, and at the same time, an etching operation may not be performed to etch the pads. In this way, the pads may be prevented from being etched, and a short circuit, which is caused by the surface of the chip being corroded by the etching solution, may be prevented.

### CROSS-REFERENCE TO RELATED APPLICATION(S)

The present application is a continuation-application of International (PCT) Patent Application No. PCT/CN2021/103811 filed Jun. 30, 2021, and the contents of which are hereby incorporated in their entireties by reference for all purposes.

### TECHNICAL FIELD

The present disclosure relates to the technical field of circuit boards, and more particularly to a method of manufacturing a package chip, a package chip, a method of manufacturing a rewiring package chip, and a rewiring package chip.

### BACKGROUND

In the art, after a package chip is manufactured, a pad on a surface of the chip may be exposed to air and may be easily oxidized, forming a layer of oxide on a surface of the pad. Alternatively, an oxide layer may be directly formed on the pads for protection. After the package chip is sold to a downstream vendor, the downstream vendor may etch the oxide layer to expose a conductive surface of the pad, and then and then perform other processing.

### SUMMARY

The present disclosure provides a method of manufacturing a package chip, a package chip, a method of manufacturing a rewiring package chip, and a rewiring package chip, in order to solve a problem that etching the oxide layer of the package chip may easily cause a channel to be defined in a surface of a chip between adjacent pads, which may result in a short circuit of the adjacent pads.

According to a first aspect of the present disclosure, a method of manufacturing a package chip is provided and includes:

providing a chip;

coating silicon dioxide on a surface of a side of the chip, wherein a plurality of pads are disposed on the surface of the chip, and a conductive surface of each of the plurality of pads contacts the silicon dioxide.

According to a second aspect of the present disclosure, a method of manufacturing a rewiring package chip is provided and includes:

providing a package chip, wherein the package chip comprises a chip and a dielectric layer covering a surface of a side of the chip, a plurality of pads are disposed on the surface of the side of the chip, the dielectric layer comprises silicon dioxide, a conductive surface of each of the plurality of pads contacts the silicon dioxide;

defining a through hole in the dielectric layer at a position corresponding to each of the plurality of pads;

performing electroplating on the chip that defines the through hole, and forming a conductive post in the through hole.

According to a third aspect of the present disclosure, a package chip is provided and includes:
a chip;
a plurality of pads, disposed on a surface of the chip; and
a dielectric layer, covering the surface of the chip where the plurality of pads are disposed and covering the plurality of pads, wherein the dielectric layer comprises silicon dioxide, and a conductive surface of each of the plurality of pads contacts the silicon dioxide.

According to a fourth aspect of the present disclosure, a rewiring package chip is provided, and the package chip includes:
a chip;
a plurality of pads, disposed on a surface of the chip;
a dielectric layer, covering the surface of the chip where the plurality of pads are disposed and defining a through hole at a position corresponding to each of the plurality of pads, wherein the dielectric layer comprises silicon dioxide, and a conductive surface of each of the plurality of pads contacts the silicon dioxide; and
a conductive post, received in the through hole, wherein an end of the conductive post is connected to each of the plurality of pads, and the other end of the conductive post is exposed from the dielectric layer.

### BRIEF DESCRIPTION OF DRAWINGS

In order to more clearly illustrate technical solutions in the embodiments of the present disclosure, the drawings used in the description of the embodiments will be described briefly in the following. Apparently, the drawings in the following description show only some of the embodiments of the present disclosure, and any ordinary skilled person in the art may obtain other drawings based on these drawings without any creative work.

FIG. 1 is a structural schematic view of a package chip in the art.

FIG. 2 is a flow chart of a method of manufacturing a package chip according to an embodiment of the present disclosure.

FIG. 3 is a flow chart of a method of manufacturing a rewiring package chip according to an embodiment of the present disclosure.

FIG. 4 is a structural schematic view of a package chip according to an embodiment of the present disclosure.

FIG. 5 is a structural schematic view of a rewiring package chip according to an embodiment of the present disclosure.

### DETAILED DESCRIPTION

The present disclosure is described in further detail below by referring to the accompanying drawings and embodiments. It is particularly noted that the following embodiments are used to illustrate the present disclosure only, but do not limit the scope of the present disclosure. Similarly, the following embodiments are only some but not all embodiments of the present disclosure. All other embodiments obtained by an ordinary skilled person in the art without creative work shall fall within the scope of the present disclosure.

Terms “inside” and “outside” in the specification and claims of the present disclosure and the above-mentioned drawings indicate an orientation or a position relationship based on what is shown in the drawings, or an orientation or a position relationship in which the product is customarily placed while in use. The terms are used to facilitate the description of the present disclosure and to simplify the description, but do not indicate or imply that a device or a component referred to must have the specific orientation, or the device or the component referred to must be constructed and operated in the specific orientation. Therefore, the terms cannot be interpreted as a limitation of the present disclosure.

Terms “first”, “second”, “third”, “fourth”, and so on (if present, in the specification, claims, and the accompanying drawings are used to distinguish similar objects, but are not necessarily used to describe a particular order or sequence. It shall be understood that data described in this way is interchangeable where appropriate, such that embodiments of the present disclosure described herein can be implemented in an order other than those illustrated or described herein. In addition, terms “including”, “having”, and any variations thereof, are intended to describe non-exclusive inclusion.

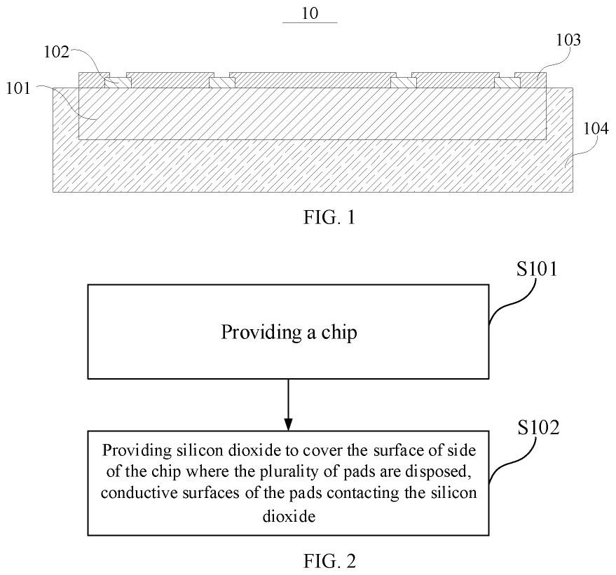

As shown in FIG. 1, FIG. 1 is a structural schematic view of a package chip in the art. The package chip 10 in the art includes a chip 101, a plurality of pads 102, a photoresist 103 and an encapsulation resin 104. The plurality of pads 102 are disposed on a surface of a side of the chip 101. The surface of the chip 101 where the plurality of pads 102 are disposed and surfaces of the plurality of pads 102 are arranged with an oxide layer. In addition, the photoresist 103 covers the surface of the chip 101 where the pads 102 are disposed and exposes a part of a surface of the oxide layer on the surfaces of the pads 102. The encapsulation resin 104 covers all surfaces of the chip 101 other than the surface where the pads 102 are disposed. In order to allow subsequent processing to be performed easily, the oxide layer on the surfaces of the pads 102 needs to be removed. In detail, an acidic solution or an alkaline solution may be required to clean the surfaces. While cleaning, the acidic solution or the alkaline solution may corrode the surfaces of the pads 102 and the oxide layer on the surface of the chip 101, such that a channel in a certain depth (not shown) may be defined between adjacent pads 102. A part of the solution may remain in the channel. The solution in the channel may cause the adjacent pads 102 to be conductive, resulting in a short circuit between the adjacent pads 102, and eventually causing the package chip 10 to fail to work properly.

As shown in FIG. 2, FIG. 2 is a flow chart of a method of manufacturing a package chip according to an embodiment of the present disclosure.

In an operation S101, a chip is provided.

In the present embodiment, a plurality of pads are formed on a surface of a side of the chip. The chip may be conductive to an external component through the plurality of pads. The pads may be made of nickel, copper, titanium or formed by laminated layers thereof. For example, each pad may be a Al/Cu pad or a Ti/Cu pad. In detail, each pad may include a titanium layer and a copper layer disposed above the titanium layer. Alternatively, the pad may include an aluminum layer and a copper layer disposed above the aluminum layer.

In an operation S102, silicon dioxide covers the surface of side of the chip where the plurality of pads are disposed, conductive surfaces of the pads contacts the silicon dioxide.

In the present embodiment, after the plurality of pads are formed on the surface of the side of the chip, a dielectric layer may be configured to cover the surface of the side of the chip where the plurality of pads are disposed. The conductive surfaces of the pads contacts the dielectric layer. By arranging the dielectric layer to cover the surface of the side of the chip where the plurality of pads are disposed, air tightness of the chip may be improved. The dielectric layer covering the plurality of pads may prevent the surfaces of the pads from being exposed to be oxidized by the air, thereby preventing an oxide layer from being formed.

In an embodiment, the dielectric layer may be silicon dioxide. The silicon dioxide may be configured to cover the surface of the side of the chip where the plurality of pads are disposed, such that the silicon dioxide contacts the surface of the chip and conductive surfaces of the pads. The dielectric layer covers entire exposed surfaces of the pads, such that the entire surfaces do not contact the air. In detail, physical or chemical vapour deposition may be performed to coat the silicon dioxide on the surface of the side of the chip where the plurality of pads are disposed. In this way, the silicon dioxide may cover the surface of the side of the chip where the plurality of pads are disposed. In the present embodiment, the silicon dioxide is arranged, replacing the photoresist in the art, reducing manufacturing costs.

Alternatively, after the dielectric layer covering the surface of the side of the chip where the plurality of pads are disposed, the chip is further encapsulated. In detail, the chip and the silicon dioxide may be wrapped by resin. Encapsulation by the resin may avoid electrical performance degradation caused by corrosion of the chip by impurities in the air, such that an exterior of the chip and a connection lead may be protected.

In another embodiment, the dielectric layer may be resin. Arranging the resin to cover the surface of the side of the chip where the plurality of pads are disposed allows the resin to contact the surface of the chip and the conductive surfaces of the pads. In detail, the resin is coated to surface of the side of the chip where the plurality of pads are disposed. Subsequently, the resin may be heated and cured to form the dielectric layer. In this way, the resin may cover the surface of the side of the chip where the plurality of pads are disposed. Surfaces of the pads and the chip may be prevented from being corroded by the solution, and the chip may be encapsulated.

According to the present disclosure, the dielectric layer covers the surface of the side of the chip where the pads are disposed, and the conductive surfaces of the pads contact the dielectric layer. Since the dielectric layer covering the surface of the chip and the conductive surfaces of the pads does not need to be partially removed by etching, the air tightness of the package chip may be improved to prevent the pads from being oxidized by the air, and at the same time, an etching operation may not be performed to etch the pads. In this way, the pads may be prevented from being etched, and a short circuit, which is caused by the surface of the chip being corroded by the etching solution, may be prevented. Further, the manufacturing costs may be reduced.

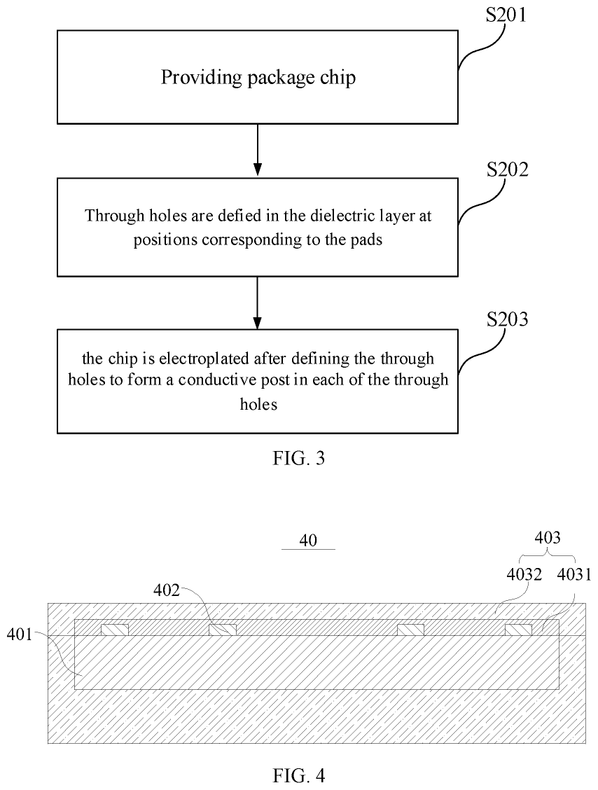

As shown in FIG. 3, FIG. 3 is a flow chart of a method of manufacturing a rewiring package chip according to an embodiment of the present disclosure.

In an operation S201, a package chip is provided.

After the package chip from an upstream manufacturer passes to a downstream vendor, the package chip needs to be further processed. In the present embodiment, the downstream vendor prepares a package chip that requires further processing. The package chip may include the chip and the dielectric layer covering the surface of the side of the chip where the plurality of pads are disposed. The conductive surfaces of the pads contact the dielectric layer.

In an embodiment, the dielectric layer includes a first dielectric layer that contacts the surfaces of the pads and a second dielectric layer that encases the chip and the first dielectric layer. The first dielectric layer is formed by performing the physical or chemical vapour deposition on the silicon dioxide. The second dielectric layer is formed by curing the resin. Alternatively, before curing the resin, surfaces need to be cleaned by an acidic solution or an alkaline solution to remove surface impurities, preventing the impurities from affecting performance of the chip. Since the first dielectric layer contacts the surface of the chip and the conductive surfaces of the pads, the air tightness of the chip may be improved, preventing the chip from being damaged by the solution. In addition, the first dielectric layer may prevent the surfaces of the pads from being exposed to be oxidized by the air, and an oxide layer may be prevented from being formed on the surfaces of the pads. The second dielectric layer may encapsulate the chip to avoid electrical performance degradation caused by corrosion of chip circuits by impurities in the air, such that an exterior of the chip and a connection lead may be protected.

In an operation S202, through holes are defined in the dielectric layer at positions corresponding to the pads.

In the present embodiment, the dielectric layer covers the surface of the side of the chip where the pads are disposed, and the package chip needs to be connected to the external component through the pads. Therefore, through holes need to be defined in the dielectric layer at positions corresponding to the pads to remove a portion of the dielectric layer covering the surfaces of the pads, and the package chip may be connected to the external component through the through holes.

In an embodiment, the dielectric layer includes a first dielectric layer that contacts the surfaces of the pads and a second dielectric layer that encases the chip and the first dielectric layer. In detail, through holes are defined in the first dielectric layer and the second dielectric layer at positions corresponding to the pads. The second dielectric layer is formed by curing the resin. Therefore, a portion of the resin at the positions corresponding to the pads may be removed by laser drilling. The first dielectric layer may be formed by performing the physical deposition or chemical vapour deposition on the silicon dioxide. Therefore, the silicon dioxide of the first dielectric layer at the positions corresponding to the pads may be removed by a plasma or an acidic etching solution. In this way, through holes are defined. The through holes are acid etched holes or plasma bombardment holes. Therefore, being different from holes, which are defined by the etching solution and have an uneven hole wall, a hole wall of each of the plasma bombardment holes in the present disclosure may be axially smooth. Positions of the through holes may first be determined by laser drilling. Subsequently, the plasma or the acid etching operation may be performed to define the through holes precisely without damaging the pads. in addition, the through holes may be defined at any position of the pads. Compared to the package chip in the art which exposes a part of each of the plurality of pads, a larger area may be available in the present disclosure for defining the through holes, and positions of the through holes may be determined more accurately. In this way, a part of the through holes may be prevented from being defined in a region outside the pads, improving a yield of package chips. In addition, an area of each pad does not need to be manufactured to be large for preventing the through hole from being defined outside the pad.

In an operation S203, the chip is electroplated after defining the through holes to form a conductive post in each of the through holes.

In the present embodiment, after defining the through holes in the dielectric layer corresponding to the pads, the chip having the through holes is further electroplated, such that the conductive post is formed in each of the through holes. An end of the conductive post is connected to a conductive surface of a corresponding pad, and the other end is exposed to the dielectric layer. An area of a surface of the conductive post contacting the corresponding pad is not greater than that of the conductive surface of the corresponding pad. Rewiring may be performed through the conductive post to connect the chip to the external component, enabling various functions to be achieved.

According to the present disclosure, the dielectric layer covers the surface of the side of the chip where the pads are disposed, and the conductive surfaces of the pads contact the dielectric layer. Since the dielectric layer covering the surface of the chip and the conductive surfaces of the pads does not need to be partially removed by etching, the air tightness of the package chip may be improved to prevent the pads from being oxidized by the air, and at the same time, the etching operation may not be performed to etch the pads. In this way, the pads may be prevented from being etched, and a short circuit, which is caused by the surface of the chip being corroded by the etching solution, may be prevented. Further, the manufacturing costs may be reduced.

FIG. 4 is a structural schematic view of a package chip according to an embodiment of the present disclosure. The package chip 40 includes a chip 401, a plurality of pads 402 and a dielectric layer 403.

In the present embodiment, the plurality of pads 402 are disposed on a surface of a side of the chip 401. The pads 402 may be made of nickel, copper, titanium or formed from laminated layers thereof. For example, each pad may be an Al/Cu pad or a Ti/Cu pad. Each pad 402 may include a titanium layer and a copper layer disposed above the titanium layer. Alternatively, the pad 402 may include an aluminum layer and a copper layer disposed above the aluminum layer.

The dielectric layer 403 covers the surface of the side of the chip 401 where the plurality of pads 402 are disposed. The dielectric layer 403 covers the plurality of pads 402. The dielectric layer 403 covers an entire exposed surface of each pad 402, such that the entire surface of the pad 402 does not contact the air.

In an embodiment, the conductive surface of the pad 402 contacts the dielectric layer 403. The number of dielectric layers 403 may be two, including a first dielectric layer 4031 and a second dielectric layer 4032. The first dielectric layer 4031 may be disposed between the second dielectric layer 4032 and the surface of the chip 401. The first dielectric layer 4031 may include silicon dioxide. The silicon dioxide may be coated to the surface of the side of the chip 401 where the plurality of pads 402 are disposed by physical or chemical vapour deposition, forming the first dielectric layer 4031. The second dielectric layer 4032 may include resin. The second dielectric layer 4032 wraps the chip 401 and the first dielectric layer 4031 to avoid electrical performance degradation caused by corrosion of the chip circuit by impurities in the air, and the exterior of the chip and the connection lead may be protected.

According to the present disclosure, the dielectric layer covers the surface of the side of the chip where the pads are disposed, and the dielectric layer covers the conductive surfaces of the pads. Since the dielectric layer covering the surface of the chip and the conductive surfaces of the pads does not need to be partially removed by etching, the air tightness of the package chip may be improved to prevent the pads from being oxidized by the air, and at the same time, the etching operation may not be performed to etch the pads. In this way, the pads may be prevented from being etched, and a short circuit, which is caused by the surface of the chip being corroded by the etching solution, may be prevented. Further, the manufacturing costs may be reduced.

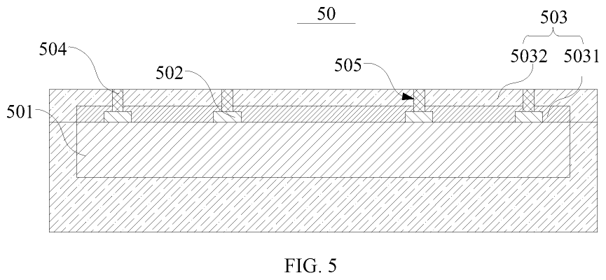

FIG. 5 is a structural schematic view of a rewiring package chip according to an embodiment of the present disclosure. The rewiring package chip 50 includes a chip 501, a plurality of pads 502, a dielectric layer 503 and a plurality of conductive posts 504.

In the present embodiment, the plurality of pads 502 are disposed on a surface of a side of the chip 501. The pads 502 may be made of nickel, copper, titanium or formed from laminated layers thereof. For example, each pad may be an Al/Cu pad or a Ti/Cu pad. Each pad 502 may include a titanium layer and a copper layer disposed above the titanium layer. Alternatively, the pad 502 may include an aluminum layer and a copper layer disposed above the aluminum layer.

The dielectric layer 503 covers the surface of the side of the chip 501 where the plurality of pads 502 are disposed. The dielectric layer 503 covers the plurality of pads 502. The dielectric layer 503 covers the entire exposed surface of each of the plurality of pads 502, such that the entire surface of each pad 502 does not contact the air. The dielectric layer 503 defines a plurality of through holes 505 at positions corresponding to the plurality of pads 501. A surface of a wall of each of the plurality of through holes 505 is axially smooth. The plurality of through holes 505 are laser burned holes or plasma bombardment holes.

In an embodiment, the conductive surface of each pad 502 contacts the dielectric layer 403. The number of dielectric layers 503 may be two, including a first dielectric layer 5031 and a second dielectric layer 5032. The first dielectric layer 5031 may be disposed between the second dielectric layer 5032 and the surface of the chip 501. The first dielectric layer 5031 may include silicon dioxide. The silicon dioxide may be coated to the surface of the side of the chip 501 where the plurality of pads 502 are disposed by physical or chemical vapour deposition, forming the first dielectric layer 5031. The second dielectric layer 5032 may include resin. The second dielectric layer 5032 wraps the chip 501 and the first dielectric layer 5031 to avoid electrical performance degradation caused by corrosion of the chip circuit by impurities in the air, and the exterior of the chip and the connection lead may be protected.

The through holes 505 are formed by removing the resin at the positions of the second dielectric layer 5032 corresponding to the pads by laser drilling, and subsequently, removing the silicon dioxide at the positions of the first dielectric layer 5031 corresponding to the pads by plasma or acidic etching solution. The through holes 505 may be defined at any position of the pads 502. Compared to the chip in the art, which exposes a part of each pad, a larger area may be available in the present disclosure for defining the through holes, and positions of the through holes may be determined more accurately. In this way, a part of the through holes 505 may be prevented from being defined in a region outside the pads 502, improving a yield of package chips. In addition, an area of each pad 502 does not need to be manufactured to be large for preventing the through hole 505 from being defined outside the pad 502.

In the present embodiment, each conductive post 504 is received in a corresponding through hole 505. An end of the conductive post 504 is connected to a corresponding pad 502, and the other end of the conductive post 504 is exposed to the dielectric layer 503. Each conductive post 504 may be a copper pillar and may be formed by performing electroplating on each through hole 505. The conductive posts 504 may be configured to conduct the chip 501 to the external component to achieve various functions. The conductive post 504 may be configured at any position of the conductive surface of the pad 502. Compared to exposing a part of the pad in the art, an area of the pad 502 for defining the conductive post 504 may be larger, and a part of the conductive post 504 may be prevented from being arranged in a region outside the pad, improving a yield of package chips.

According to the present disclosure, the dielectric layer covers the surface of the side of the chip where the pads are disposed, and the dielectric layer covers the pads. Since the dielectric layer covering the surface of the chip and the conductive surfaces of the pads does not need to be partially removed by etching, the air tightness of the package chip may be improved to prevent the pads from being oxidized by the air, and at the same time, the etching operation may not be performed to etch the pads. In this way, the pads may be prevented from being etched, and a short circuit, which is caused by the surface of the chip being corroded by the etching solution, may be prevented. In addition, a larger area may be available in the present disclosure for defining the through holes, and positions of the through holes may be determined more accurately. In this way, a part of the through holes may be prevented from being defined in a region outside the pads, improving a yield of package chips. In addition, an area of each pad does not need to be manufactured to be large for preventing the through hole from being defined outside the pad.

The above shows only an example of the present disclosure but does not limit the scope of the present disclosure. Any equivalent structure or equivalent process transformation performed based on the specification and the accompanying drawings of the present disclosure, applied directly or indirectly in other related fields, shall be equally covered by the present disclosure.

What is claimed is:

1. A method of manufacturing a package chip, comprising:
providing a chip;
coating silicon dioxide on a surface of a side of the chip, wherein a plurality of pads are disposed on the surface of the chip, and a conductive surface of each of the plurality of pads contacts the silicon dioxide.

2. The method according to claim 1, wherein coating silicon dioxide on the surface of the side of the chip where the plurality of pads are disposed comprises:
coating the silicon dioxide on the surface of the side of the chip where the plurality of pads are disposed, allowing the silicon dioxide to contact the surface of the chip and the conductive surface of each of the plurality of pads; and
providing resin to wrap around the chip and the silicon dioxide.

3. A method of manufacturing a rewiring package chip, comprising:
providing a package chip, wherein the package chip comprises a chip and a dielectric layer covering a surface of a side of the chip, a plurality of pads are disposed on the surface of the side of the chip, the dielectric layer comprises silicon dioxide, a conductive surface of each of the plurality of pads contacts the silicon dioxide;
defining a through hole in the dielectric layer at a position corresponding to each of the plurality of pads; and
performing electroplating on the chip that defines the through hole, and forming a conductive post in the through hole.

4. The method according to claim 3, wherein,
the dielectric layer comprises a first dielectric layer covering the conductive surface of each of the plurality of pads and a second dielectric layer wrapping around the first dielectric layer and the chip; and
the defining a through hole in the dielectric layer at a position corresponding to each of the plurality of pads, comprises:
defining the through hole in the first dielectric layer and in the second dielectric layer at positions corresponding to each of the plurality of pads; and
performing electroplating on the chip that defines the through hole, and forming the conductive post in the through hole.

5. The method according to claim 4, wherein, the first dielectric layer is formed by performing physical or chemical vapour deposition on silicon dioxide, the second dielectric layer is formed by curing resin, and the defining the through hole in the first dielectric layer and in the second dielectric layer at positions corresponding to each of the plurality of pads, comprises:
performing laser drilling to remove a portion of the resin of the second dielectric layer at the position corresponding to each of the plurality of pads; and
applying plasma or acidic etching solution to remove the silicon dioxide of the first dielectric layer at the position corresponding to each of the plurality of pads to define the through hole.

6. The method according to claim 3, wherein the defining a through hole in the dielectric layer at a position corresponding to each of the plurality of pads, comprises:
performing laser drilling to define the through hole in the dielectric layer at the position corresponding to each of the plurality of pads.

7. A rewiring package chip, comprising:
a chip;
a plurality of pads, disposed on a surface of the chip; and
a dielectric layer, covering the surface of the chip where the plurality of pads are disposed and covering the plurality of pads, wherein the dielectric layer comprises silicon dioxide, and a conductive surface of each of the plurality of pads contacts the silicon dioxide.

8. The rewiring package chip according to claim 7, wherein,
the conductive surface of each of the plurality of pads contacts the dielectric layer.

9. The rewiring package chip according to claim 7, wherein,
the dielectric layer comprises a first dielectric layer and a second dielectric layer, the first dielectric layer is disposed between the second dielectric layer and the surface of the chip.

10. The rewiring package chip according to claim 9, wherein,
the second dielectric layer is configured to wrap around the first dielectric layer and the chip.

11. The rewiring package chip according to claim 9, wherein,
the first dielectric layer comprises silicon dioxide, and the second dielectric layer comprises resin.

12. The rewiring package chip according to claim 9, wherein,
the dielectric layer defines a through hole at a position corresponding to each of the plurality of pads.

13. The rewiring package chip according to claim 12, further comprising:
a conductive post, received in the through hole, wherein an end of the conductive post is connected to each of the plurality of pads, and the other end of the conductive post is exposed from the dielectric layer.

14. The rewiring package chip according to claim 12, wherein,
the through hole is an acid etched hole or a plasma bombardment hole.
